(19) United States
(12) Patent Application Publication
(10) Pub. No.: US 2025/0271749 A1
(43) Pub. Date: Aug. 28, 2025

(54) A FREE-STANDING PELLICLE FILM COMPRISING HARM-STRUCTURES

(71) Applicant: CANATU FINLAND OY, Vantaa (FI)

(72) Inventors: Bjørn MIKLADAL, Vantaa (FI); Taneli JUNTUNEN, Vantaa (FI); Ilkka VARJOS, Vantaa (FI); Jarkko ETULA, Vantaa (FI)

(21) Appl. No.: 18/859,431

(22) PCT Filed: Mar. 14, 2023
(86) PCT No.: PCT/FI2023/050140

§ 371 Date: Oct. 23, 2024

(30) Foreign Application Priority Data
Apr. 27, 2022 (FI) 20225350

(51) Int. Cl. G03F 1/62

(52) U.S. Cl. CPC G03F 1/62

(57) ABSTRACT

A method for forming a free-standing pellicle film including high aspect ratio molecular structures (HARM-structures) is disclosed. The method includes depositing a first portion of HARM-structures onto a porous filter to form a film of HARM-structures on the porous filter, transferring the film of HARM-structures from the porous filter to a frame to form a free-standing film of HARM-structures attached to the frame, and depositing a second portion of HARMS-structures onto the free-standing film of HARM-structures attached to the frame to form a free-standing pellicle film of HARM-structures attached to the frame.

### TECHNICAL FIELD

The present disclosure relates to a method for forming a free-standing pellicle film comprising high aspect ratio molecular structures (HARM-structures). The present disclosure further relates to a free-standing pellicle film comprising high aspect ratio molecular structures (HARM-structures) attached to a frame. The present disclosure further relates to the use of the free-standing pellicle film.

### BACKGROUND

Extreme ultraviolet lithography (EUV or EUVL) is an optical lithography technology using a range of extreme ultraviolet wavelengths. EUV pellicle films are used to protect a photomask from defects, enhance precision, shorten processing, and increase production efficiency on a wafer. However, defects in printing remain a key constraint to EUV lithography uptake. Thus, a sophisticated particle filters like the EUV pellicle film are needed.

### SUMMARY

A method for forming a free-standing pellicle film is disclosed. The method for forming a free-standing pellicle film comprising high aspect ratio molecular structures (HARM-structures) comprises:
a) depositing a first portion of HARM-structures onto a porous filter to form a film of HARM-structures on the porous filter,
b) transferring the film of HARM-structures from the porous filter to a frame to form a free-standing film of HARM-structures attached to the frame, and
c) depositing a second portion of HARMS-structures onto the free-standing film of HARM-structures attached to the frame to form the free-standing pellicle film of HARM-structures attached to the frame.

Further, a free-standing pellicle film comprising high aspect ratio molecular structures (HARM-structures) attached to a frame is disclosed. The free-standing pellicle film of HARM-structures exhibits a transmittance difference value of at most 1% when calculated following the formula of:

$$transmittance difference value ( \% ) = maximum transmittance ( \% ) - minimum transmittance ( \% ) ,$$

wherein
maximum transmittance is the maximum value of transmittance measured at the wavelength of 550 nm for the free-standing pellicle film of HARM-structures;
minimum transmittance is the minimum value of transmittance measured at the wavelength of 550 nm for the free-standing pellicle film of HARM-structures.

Further is disclosed the use of a free-standing pellicle film in extreme ultraviolet lithography; as an extreme ultraviolet membrane; as an extreme ultraviolet debris filter; or as a pellicle film for an X-ray window.

### BRIEF DESCRIPTION OF THE DRAWINGS

The accompanying drawing, which is included to provide a further understanding of the embodiments and constitutes a part of this specification, illustrates an embodiment. In the drawings:

FIG. 1 illustrates the method for forming a free-standing pellicle film of HARM-structures according to one embodiment;

FIG. 2 illustrates the optical measurement device setup for measuring the transmittance;

FIG. 3 and FIG. 4 illustrates defect images.

### DETAILED DESCRIPTION

The present disclosure relates to a method for forming a free-standing pellicle film comprising high aspect ratio molecular structures (HARM-structures), wherein the method comprises:
a) depositing a first portion of HARM-structures onto a porous filter to form a film of HARM-structures on the porous filter,
b) transferring the film of HARM-structures from the porous filter to a frame to form a free-standing film of HARM-structures attached to the frame, and
c) depositing a second portion of HARMS-structures onto the free-standing film of HARM-structures attached to the frame to form a free-standing pellicle film of HARM-structures attached to the frame.

In one embodiment, the deposition of the first portion of HARM-structures and/or the second portion of HARM-structures are/is deposited from a gas phase. In one embodiment, step a) is carried out by depositing a first portion of HARM-structures from a gas phase onto a porous filter to form a film of HARM-structures on the porous filter. In one embodiment, step c) is carried out by depositing a second portion of HARMS-structures from the gas phase onto the free-standing film of HARM-structures attached to the frame to form a free-standing pellicle film of HARM-structures attached to the frame.

Porous filters may be used when depositing HARM-structures to form a layer or film thereof. The porous filter may be a non-woven filter or a woven filter. The porous filter may be made of mixed cellulose ester (MCE), polyethersulfone (PES), track etched polycarbonate, electrospun (PVDF) or polyethylene terephthalate (PET), polyamide, metal, or glass fiber. The material of the porous filter may be selected such that when depositing the HARM-structures thereon from e.g. the gas phase, the HARM-structures are remained on the porous filter whereby the gas itself, i.e. the carrier gas, is filtered through the porous filter.

Typically, porous filters, as well as most surfaces, do not have smooth and defect free surfaces but may contain multiple defects in the form of small holes or bumps and regions of high and low porosity. These porous filter defects may in turn affect the uniformity of the film that is deposited onto the porous filter. These defects may decrease mechanical properties of the pellicle film and weaken the particle filtration capabilities of the pellicle film, e.g. in particle filtration or EUV pellicle applications.

Typically efforts have been made on seeking to provide a filter with as smooth and defect-free surface as possible for deposition in order reduce non-uniformity of the deposited film. However, the inventors surprisingly found out that when firstly depositing a part of the HARM-structures on the porous filter and then, after transferring the formed film of HARM-structures to a frame, to deposit another part of HARM-structures directly on the free-standing film of HARM-structures one is able to efficiently reduce defects in the produced free-standing pellicle film of HARM-structures. Without bounding to any specific theory why a highly smooth free-standing pellicle film of HARM-structures may be formed by the stepwise deposition of HARM-structures as disclosed in the current specification, one may consider that when depositing the second part of the HARM-structures on the free-standing film of HARM-structures, the thinner parts of the free-standing film of HARM-structures may pass through a greater part of the gas with the HARM-structures than the thicker parts. This may result in the fact that a greater amount of HARM-structures are deposited on or within the possible defects of the free-standing film of HARM-structures than on the remaining parts of the film.

The expression “defects” should be understood in this specification, unless otherwise stated, as micro-holes, thinner areas, dents, small holes, bumps, or regions of high and low porosity of the pellicle film.

The present disclosure further relates to a free-standing pellicle film comprising high aspect ratio molecular structures (HARM-structures) attached to a frame, wherein the free-standing pellicle film of HARM-structures exhibits a transmittance difference value of at most 1% when calculated following the formula of:

$$transmittance difference value ( \% ) = maximum transmittance ( \% ) - minimum transmittance ( \% ) ,$$

wherein
maximum transmittance is the maximum value of transmittance measured at the wavelength of 550 nm for the free-standing pellicle film of HARM-structures;
minimum transmittance is the minimum value of transmittance measured at the wavelength of 550 nm for the free-standing pellicle film of HARM-structures.

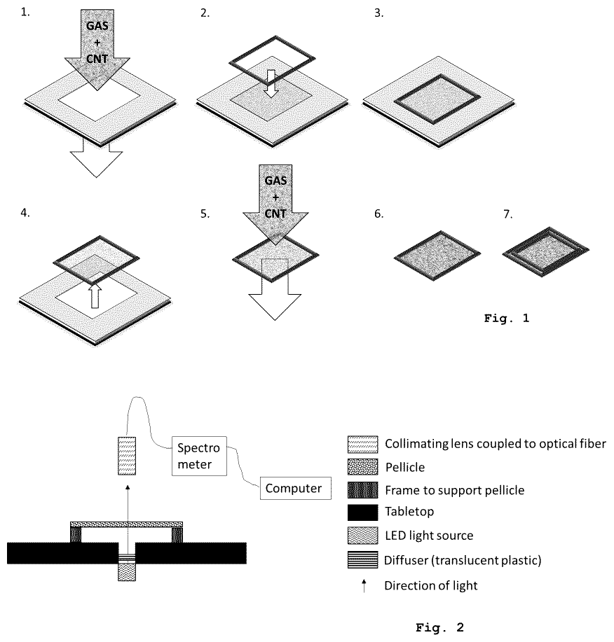

The transmittance may be measured by using an optical measurement device setup as presented in FIG. 2 in accordance with the following: The device is calibrated to 100% T and 0% T. The frame with the pellicle attached is placed on a table in between the LED light source and the collimating lens. The distance between the LED and the collimator is set at 5 cm and the light spot size is about 3 mm. The LED type used is Moonstone 3W High Brightness Power LED light source (color temperature 4000 K to 10000 K, 110 degrees viewing angle, product ASMT-MWE2-NNP00) and the spectrometer is Ocean Insight STS-VIS-L-25-400-SMA (range: 350-800 nm). The % T (% transmittance) value is recorded.

For determining the transmittance difference value, one % T measurement point is taken for each square centimetre (cm2) of the sample. The maximum and minimum values measured are used for calculating the transmittance difference value (%).

The present disclosure further relates to the use of a free-standing pellicle film as disclosed in the current specification in extreme ultraviolet lithography; as an extreme ultraviolet membrane; as an extreme ultraviolet debris filter; or as a pellicle film for an X-ray window. In one embodiment, the free-standing pellicle film is a pellicle film for extreme ultraviolet lithography; an extreme ultraviolet membrane; an extreme ultraviolet debris filter; or a pellicle film for an X-ray window.

The expression a “HARM-structure” or “HARMS” should be understood in this specification, unless otherwise stated, as referring to “nanostructures”, i.e. structures with one or more characteristic dimensions in nanometer scale, i.e. less or equal than about 100 nanometers. “High aspect ratio” refers to dimensions of the conductive structures in two perpendicular directions being in significantly different magnitudes of order. For example, a nanostructure may have a length which is tens or hundreds times higher than its thickness and/or width. In a film of HARM-structures, a great number of said nanostructures are interconnected with each other to form a network of interconnected molecules. As considered at a macroscopic scale, a HARMS network forms a solid, monolithic material in which the individual molecular structures are disoriented or non-oriented, i.e. are oriented substantially randomly, or oriented. Various types of HARM-structure networks can be produced in the form of thin transparent layers with reasonable resistivity. In one embodiment, the HARM-structures are electrically conductive HARM-structures.

In one embodiment, the HARM-structures are carbon nanostructures. In one embodiment, the carbon nanostructures comprise carbon nanotubes, carbon nanobuds, carbon nanoribbons, or any combination thereof. In one embodiment, the carbon nanostructures comprise carbon nanotubes and/or carbon nanobuds. The carbon nanobuds, or the carbon nanobud molecules as they also may be called, have fullerene or fullerene-like molecules covalently bonded to the side of a tubular carbon molecule.

In one embodiment, the method comprises, prior to step a), the step of forming or producing HARM-structures as an aerosol in a gas phase. I.e. HARM-structures may be initially produced in a gas phase in a reactor from which they may be deposited onto the porous filter or the free-standing film of HARM-structures, respectively. The deposition as such may be carried out by allowing a gas flow, e.g. a carrier gas with the HARM-structures, to pass through the porous filter or the free-standing film, whereby the HARM-structures are remained on the porous filter or the free-standing film forming a deposit of HARM-structures thereon, while the carrier gas may be passed through the porous filter or the free-standing film. The HARM-structures may be deposited from the gas phase e.g. via filtration.

The deposition may be carried out by passing a gas flow comprising HARM-structures through the porous filter or the free-standing film of HARM-structures with a total gas flow rate of 5-500 l/min. The gas flow rate may be e.g. 5-30 l/min; or alternatively 30-90 l/min, or 40-80 I/min, or 50-70 l/min; or alternatively 90-500 l/min, or 100-450 l/min, or 150-400 l/min. The higher the flow rate, the higher is the throughput of passing the gas flow through the porous filter of the free-standing film of HARM-structures thus affecting the costs involved in the process.

In one embodiment, formed is a free-standing pellicle film of HARM-structures exhibiting a transmittance difference value of at most 1% when calculated following the formula of:

$$transmittance difference value ( \% ) = maximum transmittance ( \% ) - minimum transmittance ( \% ) ,$$

wherein
maximum transmittance is the maximum value of transmittance measured at the wavelength of 550 nm for the free-standing pellicle film of HARM-structures;
minimum transmittance is the minimum value of transmittance measured at the wavelength of 550 nm for the free-standing pellicle film of HARM-structures.

In one embodiment, the free-standing pellicle film of HARM-structures comprises at most 10, or at most 5, or at most 3, or at most 1, or 0, defect(s) per cm2. In one embodiment, the free-standing pellicle film of HARM-structures comprises 0-10, or 1-5, or 1-3, defects per cm2. As such a defect may be considered a defect, which is above 15 μm, or above 12 μm, or above 9 μm, or above 7 μm, or above 5 μm, or above 3 μm, or above 2.5 μm, or above 1.5 μm, or above 1 μm, or above 0.5 μm, or above 0.3 μm, or above 0.15 μm, in size in at least one direction. In one embodiment, the free-standing pellicle film of HARM-structures comprises at most 10, or at most 5, or at most 3, or at most 1, or 0, defect(s) per cm2 having a size of above 15 μm, or above 12 μm, or above 9 μm, or above 7 μm, or above 5 μm, or above 3 μm, or above 2.5 μm, or above 1.5 μm, or above 1 μm, or above 0.5 μm, or above 0.3 μm, or above 0.15 μm, in at least one direction.

The inventors surprisingly found out that by the method as disclosed in the current specification one may be able to reduce the number of defects present in the free-standing pellicle film of HARM-structures compared to depositing all of the HARM-structures directly only on a porous filter. The number of defects may be determined by using an optical microscope setup, such as Olympus MX63L with the difference that instead of an eyepiece, a camera is used. The following parameters may be used:
light source: Olympus BX3M LEDR led light source for reflected light;
objective: 10× (Olympus MPLFLN20XBD plan fluorite objectives)
working distance: 6.5 mm;
imaging device: DP28-CU Microscope camera;
resolution: 0.68 μm/pixel;
stage: Motorized XY stage;
image analysis software: Olympus stream motion and ImageJ 1.52a.
   The frame with the free-standing pellicle film of HARM-structures is placed onto the microscope XY stage, below the microscope objective. Using the microscope software, the stage is moved to a vertical position (Z-axis) where the surface of the free-standing pellicle film of HARM-structures is in focus of the objective. Using the computer software, the user then inspects the images taken of the surface. The defective areas are identified as darker areas because the microscope acquires the image using light reflected from the surface of the sample, hence holes or areas with less HARM-structures appear darker, as less light is reflected from those areas.

In one embodiment, the free-standing pellicle film of HARM-structures exhibits a transmittance difference value of at most 0.8%, or at most 0.7%, or at most 0.6%, or at most 0.5%, or at most 0.4%, or at most 0.35%, at most 0.33%, or at most 0.30%, or at most 0.25%, or at most 0.20%, or at most 0.15%, or at most 0.10%, or at most 0.05%.

The deposition of the first portion of HARM-structures and the deposition of the second portion of HARM-structures may be continued until a predetermined or desired transmittance is achieved. One may deposit a rather thin film of HARM-structures during the deposition of the first portion of HARM-structures or alternatively a thicker film of HARM-structures may be deposited. The same applies for the step of depositing the second portion of HARM-structures on the free-standing film of HARM-structures, i.e. either a thick or thin deposition may be formed. Thus, the deposition of the first portion of HARM-structures may be continued until the transmittance of the film of HARM-structures is 1-99%. Further, the deposition of the second portion of HARM-structures may be continued until the transmittance of the free-standing pellicle film of HARM-structures has reached a predetermined or desired value.

In one embodiment, the deposition of the first portion of HARM-structures is continued until the transmittance of the film of HARM-structures is 80-99%, or 85-98%, or 90-96%, or 92-94%, of the energy of light per unit time incident perpendicularly thereon when measured at the wavelength of 550 nm. In one embodiment, the deposition of the first portion of HARM-structures is continued until the transmittance of the film of HARM-structures is 90-99%, or 92-98%, or 94-96%, of the energy of light per unit time incident perpendicularly thereon when measured at the wavelength of 550 nm. The transmittance of the formed deposition on the porous filter may be measured in situ with a camera. Any suitable camera may be used. As an example only a 10 bit, 1.6 MP monochrome camera may be mentioned. The final transmittance value may then be determined after having transferred the film of HARM-structures to the frame.

In one embodiment, the deposition of the second portion of HARM-structures is continued until the transmittance of the free-standing pellicle film of HARM-structures is 50-95%, or 55-93%, or 60-87%, or 65-86%, or 70-85%, or 75-80%, of the energy of light per unit time incident perpendicularly thereon when measured at the wavelength of 550 nm. In one embodiment, the deposition of the second portion of HARM-structures is continued until the transmittance of the free-standing pellicle film of HARM-structures is 80-87%, or 81-86%, or 82-85%, of the energy of light per unit time incident perpendicularly thereon when measured at the wavelength of 550 nm.

The transmittance or transparency of a film primarily refers to the transparency in the thickness direction of the film, or the parts thereof, so that in order to be “transparent”, sufficient portion of light energy incident on the film, or a part thereof, shall propagate through it in the thickness direction.

In one embodiment, the deposition of the first portion of HARM-structures is continued until the thickness of the film of HARM-structures is 3-50 nm, or 5-45 nm, or 7-40 nm, or 10-35 nm, or 15-30 nm, or 20-25 nm. In one embodiment, the deposition of the second portion of HARM-structures is continued until the thickness of the free-standing pellicle film of HARM-structures is 75-400 nm, or 76-350 nm, or 77-300 nm, or 78-250 nm, or 79-200 nm, or 80-160 nm, or 81-140 nm, or 82-120 nm, or 83-110 nm, or 84-100 nm, or 85-90 nm. The thickness of the film may be measured with a contact profilometer, such as atomic force microscopy (AFM), or an optical profilometer.

In one embodiment, the method comprises depositing the first portion of HARM-structures until the thickness of the film of HARM-structures is 99-75%, or 95-85%, of the total thickness of the free-standing pellicle film of HARM-structures to be formed. In one embodiment, the method comprises depositing the first portion of HARM-structures until the thickness of the film of HARM-structures is 99-95%, or 95-85%, or 85-75%, of the total thickness of the free-standing pellicle film of HARM-structures to be formed.

In one embodiment, the formed free-standing pellicle film of HARM-structures is set to have a predetermined transmittance value, and the deposition of the first portion of HARM-structures is continued until the film of HARM-structures exhibits transmittance, which is 75-15%, or 65-35%, or 55-35%, of the predetermined transmittance value. In one embodiment, the formed free-standing pellicle film of HARM-structures is set to have a predetermined transmittance value, and the deposition of the first portion of HARM-structures is continued until the film of HARM-structures exhibits transmittance, which is 75-65%, or 65-55%, or 55-35%, 35-15%, of the predetermined transmittance value.

The film of HARM-structures formed on the porous filter in step a) is transferred to a frame in step b) to form a free-standing film of HARM-structures. The frame may support the free-standing film of HARM-structures, or the free-standing pellicle film of HARM-structures at a later stage, at the outer edges thereof such that an unsupported standalone region of the free-standing (pellicle) film of HARM-structures is formed. The support positions may be located anywhere in the structure as long as they provide sufficient support for the free-standing (pellicle) film of HARM-structures. For example, they may be on the sides of the free-standing (pellicle) film of HARM-structures, or in areas near corners, or next to each other along the sides. Any wider area that includes a plurality of support points is also meant to be covered by this aspect, for example if the frame has an uninterrupted circular shape wherein the free-standing region lies within the circle. The frame may also have any other prolonged uninterrupted shape. In one embodiment, the frame is shaped as a circle, a square, a triangle, a rectangle, an oval, or a polygon.

In one embodiment, the frame is made of polymer, quartz, titanium, graphite, silicon, silicon carbide, silicon nitrate, poly-silicon, a transition metal, or an alloy of transition metals.

In one embodiment, the method further comprises depositing at least one further portion of HARMS-structures or other nanomaterial onto the free-standing pellicle film of HARM-structures. In one embodiment, the method further comprises depositing at least one further portion of HARMS-structures or other nanomaterial from a gas phase onto the free-standing pellicle film of HARM-structures. The term “other nanomaterial” may refer to boron nitride nanotubes (BNNT), nanoplatelets, nanoribbons, nanowires, and nanofibers. As examples of nanoplatelets may be mentioned graphene nanoplatelets, boronphene nanoplatelets, boron carbide nanoplatelets. As examples of nanoribbons may be mentioned graphene nanoribbons and graphite nanoribbons. As examples of nanowires may be mentioned tungsten nanowires, copper nanowires, aluminium nanowires, nickel nanowires, or silver nanowires. As examples of nanofibers may be mentioned carbon nanofibers and silicon carbide nanofibers. In one embodiment, the method further comprises depositing a polymer on the free-standing pellicle film of HARM-structures. Depositing further portions of the same or different nanomaterials on the free-standing pellicle film of HARM-structures has the added utility of enabling to form a pellicle film with a hybrid material structure.

In one embodiment, the method further comprises depositing a third portion of HARMS-structures onto the free-standing pellicle film of HARM-structures. In one embodiment, the method further comprises depositing a third portion of HARMS-structures from a gas phase onto the free-standing pellicle film of HARM-structures.

In one embodiment, the method further comprises re-transferring the formed free-standing pellicle film of HARM-structures attached to the frame from the frame to a second frame, wherein the size of the second frame is smaller than the size of the frame, wherein the second frame is pushed through the free-standing pellicle film of HARM-structures attached to the frame, for stretching the free-standing pellicle film of a HARM-structures. The free-standing pellicle film of HARM-structures may thus be stretched as a result of the re-transfer, thus often enhancing the mechanical properties of the free-standing pellicle film, making the free-standing pellicle film more flat by decrease “wrinkles” that may be present.

The material of the second frame may be different from the material of the frame. Re-transferring the free-standing pellicle film of HARM-structures from the frame to a second frame has the added utility of enabling post-processing methods, which may be conducted e.g. at high temperatures or in corrosive environments that would otherwise be detrimental to other frame materials.

The method as disclosed in the current specification has the added utility of providing a free-standing pellicle film comprising HARM-structures with a smooth surface and a reduced number of defects. As the amount of defects may be reduced in the free-standing pellicle film its mechanical properties are improved. Further, the capability of the free-standing pellicle film for particle filtration may be increased.

### EXAMPLES

Reference will now be made in detail to the described embodiments, examples of which are illustrated in the accompanying drawings.

The description below discloses some embodiments in such a detail that a person skilled in the art is able to form a free-standing pellicle film comprising HARM-structures based on the disclosure. Not all steps of the embodiments are discussed in detail, as many of the steps will be obvious for the person skilled in the art based on this specification.

For reasons of simplicity, item numbers will be maintained in the following exemplary embodiments in the case of repeating components.

FIG. 1 illustrates the method for forming a free-standing pellicle film comprising HARM-structures according to one embodiment. In the embodiment of FIG. 1, firstly a first portion of HARM-structures are deposited e.g. from a gas phase onto a porous filter to form a film of HARM-structures on the porous filter (number 1 of FIG. 1).

The film of HARM-structures is transferred from the porous filter to a frame to form a free-standing film of HARM-structures attached to the frame (numbers 2-4 of FIG. 1).

Following the step of transferring the film of HARM-structures onto the frame to form a free-standing film of HARM-structures attached to the frame, a second portion of HARMS-structures are deposited e.g. from the gas phase onto the free-standing film of HARM-structures attached to the frame to form a free-standing pellicle film of HARM-structures attached to the frame (numbers 5-6 of FIG. 1).

In the embodiment of FIG. 1. is further illustrated the step of re-transferring the formed free-standing pellicle film of HARM-structures attached to the frame, from the frame to a second frame, wherein the size of the second frame is smaller than the size of the frame, wherein the second frame is pushed through the free-standing pellicle film of HARM-structures attached to the frame, for stretching the free-standing pellicle film of a HARM-structures (number 7 of FIG. 1).

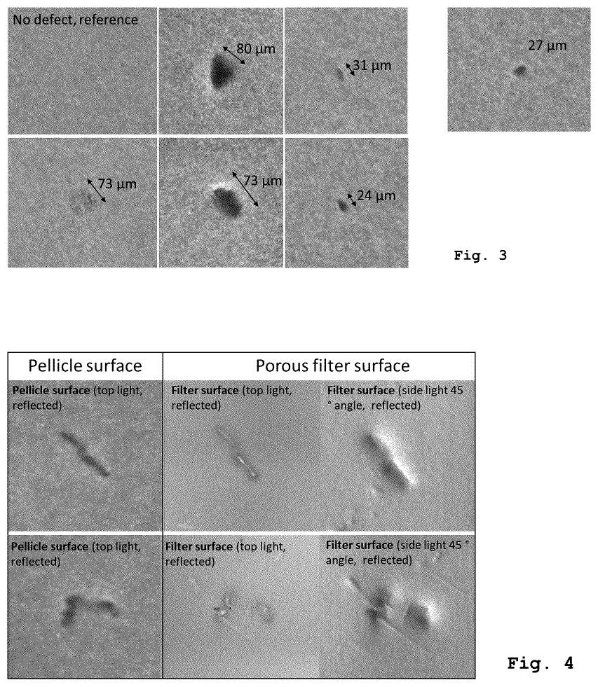

FIG. 3 illustrates images of defects on the surface of a pellicle film that may be formed. The images are taken with an Olympus MX63L microscope. The arrows show the size of defects in micrometers. These defects are dents and areas with less carbon nanotube material.

FIG. 4 illustrates how protruding defects present in the porous filter are being transferred to pellicle film formed on the porous filter by depositing HARM-structures thereon. The defects manifest themselves as dents that contain less material of HARM-structures.

### Example 1—Producing a Free-Standing Pellicle Film

In this example different free-standing pellicle films attached to a frame were produced by using the following materials:

| | Material |
|---|---|
| Porous filter | MCE* |
| Frame | Poly(methyl methacrylate) |
| HARM-structures | Carbon nanotubes |

*MCE = mixed cellulose ester
**A square frame, 111.5 mm × 144 mm inner area and 118.5 mm × 151 mm outer area

Firstly, carbon nanotubes were synthesized in an aerosol laminar flow (floating catalyst) reactor using carbon monoxide and ferrocene as a carbon source and a catalyst precursor, respectively. A first portion of the formed carbon nanotubes was deposited from the gas phase onto the porous filter at a total gas flow rate of 60 l/min (gas velocity of max 0.13 m/s) to form a film of carbon nanotubes on the porous filter. The temperature of the gas was about 60° C. The deposition of the first portion of carbon nanotubes was continued until the transmittance of the film of carbon nanotubes was 95% of the energy of light per unit time incident perpendicularly thereon when measured at the wavelength of 550 nm. The thickness of the formed film of carbon nanotubes was in the range 15-30 nm.

The formed film of carbon nanotubes was then transferred from the porous filter to the frame to form a free-standing film of carbon nanotubes attached to the frame. The frame had a rectangular form with an opening in the middle.

A second portion of carbon nanotubes was then deposited from the gas phase onto the free-standing film of carbon nanotubes attached to the frame to form a free-standing pellicle film of carbon nanotubes attached to the frame. The deposition of the second portion of carbon nanotubes was continued until the transmittance of the free-standing pellicle film of carbon nanotubes was 87% of the energy of light per unit time incident perpendicularly thereon when measured at the wavelength of 550 nm. The thickness of the formed pellicle film was 70 nm.

In addition, a comparative example was made by preparing otherwise similar free-standing pellicle films but with the second portion of carbon nanotubes being deposited from the gas phase onto the porous filter with the already formed film of carbon nanotubes thereon.

In order to evaluate the uniformity of the different pellicle films formed, the transmittance was measured as described in the current specification. Based on the measurements the transmittance difference value was calculated in the following manner:

Transmittance difference value (%)=maximum transmittance (%)−minimum transmittance (%).

The results can be seen in the below table 1:

TABLE 1
The transmittance difference values of the samples

| | Transmittance difference value |
|---|---|
| | (%) (measured at 550 nm) |
| Comparative example | 1.02 |
| Free-standing pellicle film of | 0.32 |
| carbon nanotubes | |

It can be seen from the above table 1, that the free-standing pellicle film of carbon nanotubes has a transmittance difference value of 0.32%.

Further, the number of defects were measured as described in the current specification. For these measurements the following free-standing pellicle films attached to a frame were produced by using the following materials:

| | Material |
|---|---|
| Porous filter | MCE* |
| Frame | Stains steel** |
| HARM-structures | Carbon nanotubes |

*MCE = mixed cellulose ester
**A circular frame, 21 mm inner diameter, 37 mm outer diameter
The results can be seen in the below table 2:

TABLE 2
Defects in the samples

| | | | Total | Total | | Average |
|---|---|---|---|---|---|---|
| | | % T at | area | amount | | defect |
| | Samples | 550 | inspected | of | | size |
| | analyzed*** | nm | (cm²) | defects | Defects/cm² | (μm) |
| Comparative | 3 | 87 | 5.25 | 57 | 11 (+/−2.0) | 39 (+/−22) |
| example | | | | | | |
| Free- | 3 | 87 | 5.9 | 2 | 0.3 (+/−0.38) | 45 (+/−7) |
| standing | | | | | | |
| pellicle film of | | | | | | |
| carbon | | | | | | |
| nanotubes | | | | | | |

In brackets there is 1 sigma standard deviation.
The size of the defects that were registered were above 13.0 μm for the comparative example and 38.6 μm for the free-standing pellicle film of carbon nanotubes.
***The indicated number of samples were measured and averaged.

It can be seen from the above table 2, that the free-standing pellicle film of carbon nanotubes has a clearly less defects per square centimetre than the one of the comparative example.

It is obvious to a person skilled in the art that with the advancement of technology, the basic idea may be implemented in various ways. The embodiments are thus not limited to the examples described above; instead they may vary within the scope of the claims.

The embodiments described hereinbefore may be used in any combination with each other. Several of the embodiments may be combined together to form a further embodiment. A method for forming a free-standing pellicle film comprising HARM-structures, or a free-standing pellicle film comprising HARM-structures attached to a frame, or the use, as disclosed herein, may comprise at least one of the embodiments described hereinbefore. It will be understood that the benefits and advantages described above may relate to one embodiment or may relate to several embodiments. The embodiments are not limited to those that solve any or all of the stated problems or those that have any or all of the stated benefits and advantages. It will further be understood that reference to ‘an’ item refers to one or more of those items. The term “comprising” is used in this specification to mean including the feature(s) or act(s) followed thereafter, without excluding the presence of one or more additional features or acts.

1.-23. (canceled)

24. A method for forming a free-standing pellicle film comprising high aspect ratio molecular structures (HARM-structures), wherein the method comprises:
a) depositing a first portion of HARM-structures from a gas phase onto a porous filter to form a film of HARM-structures on the porous filter,
b) transferring the film of HARM-structures from the porous filter to a frame to form a free-standing film of HARM-structures attached to the frame, and
c) depositing a second portion of HARMS-structures from the gas phase onto the free-standing film of HARM-structures attached to the frame, to form a free-standing pellicle film of HARM-structures attached to the frame.

25. The method of claim 24, wherein formed is a free-standing pellicle film of HARM-structures exhibiting a transmittance difference value of at most 1% when calculated following the formula of:
transmittance difference value (%)=maximum transmittance (%)−minimum transmittance (%),
wherein
maximum transmittance is the maximum value of transmittance measured at the wavelength of 550 nm for the free-standing pellicle film of HARM-structures; and
minimum transmittance is the minimum value of transmittance measured at the wavelength of 550 nm for the free-standing pellicle film of HARM-structures.

26. The method of claim 25, wherein the free-standing pellicle film of HARM-structures exhibits a transmittance difference value of one of: at most 0.8%, or at most 0.7%, or at most 0.6%, or at most 0.5%, or at most 0.4%, or at most 0.35%, or at most 0.33%, or at most 0.30%, or at most 0.25%, or at most 0.20%, or at most 0.15%, or at most 0.10%, or at most 0.05%.

27. The method of claim 24, wherein the free-standing pellicle film of HARM-structures comprises one of: at most 10, or at most 5, or at most 3, or at most 1, or 0, defect(s) per cm2.

28. The method of claim 24, wherein the deposition of the first portion of HARM-structures is continued until the transmittance of the film of HARM-structures is one of 80-99%, or 85-98%, or 90-96%, or 92-94%, of the energy of light per unit time incident perpendicularly thereon when measured at the wavelength of 550 nm.

29. The method of claim 24, wherein the deposition of the second portion of HARM-structures is continued until the transmittance of the free-standing pellicle film of HARM-structures is one of 50-95%, or 55-93%, or 60-87%, or 65-86%, or 70-85%, or 75-80%, of the energy of light per unit time incident perpendicularly thereon when measured at the wavelength of 550 nm.

30. The method of claim 24, wherein the deposition of the first portion of HARM-structures is continued until the thickness of the film of HARM-structures is one of 3-50 nm, or 5-45 nm, or 7-40 nm, or 10-35 nm, or 15-30 nm, or 20-25 nm.

31. The method of claim 24, wherein the deposition of the second portion of HARM-structures is continued until the thickness of the free-standing pellicle film of HARM-structures is one of 75-400 nm, or 76-350 nm, or 77-300 nm, or 78-250 nm, or 79-200 nm, or 80-160 nm, or 81-140 nm, or 82-120 nm, or 83-110 nm, or 84-100 nm, or 85-90 nm.

32. The method of claim 24, wherein the formed free-standing pellicle film of HARM-structures is set to have a predetermined transmittance value, and the deposition of the first portion of HARM-structures is continued until the film of HARM-structures exhibits transmittance, which is one of 75-15%, or 65-35%, or 55-35%, of the predetermined transmittance value.

33. The method of claim 24, wherein the frame comprises at least one of polymer, quartz, titanium, graphite, silicon, silicon carbide, silicon nitrate, poly-silicon, a transition metal, or an alloy of a transition metal.

34. The method of claim 24, wherein the method further comprises depositing at least one further portion of HARMS-structures or other nanomaterial onto the free-standing pellicle film.

35. The method of claim 24, wherein the HARM-structures are carbon nanostructures.

36. The method of claim 24, wherein the method further comprises retransferring the formed free-standing pellicle film of HARM-structures attached to the frame, from the frame to a second frame, wherein the size of the second frame is smaller than the size of the frame, wherein the second frame is pushed through the free-standing pellicle film of HARM-structures attached to the frame, for stretching the free-standing pellicle film of a HARM-structures.

37. The method of claim 24, wherein the free-standing pellicle film is a pellicle film for extreme ultraviolet lithography; an extreme ultraviolet membrane; an extreme ultraviolet debris filter; or a pellicle film for an X-ray window.

38. A free-standing pellicle film, comprising high aspect ratio molecular structures (HARM-structures), attached to a frame, wherein the free-standing pellicle film of HARM-structures exhibits a transmittance difference value of at most 1% when calculated following the formula of:
transmittance difference value (%)=maximum transmittance (%)−minimum transmittance (%),
wherein
maximum transmittance is the maximum value of the transmittance measured at the wavelength of 550 nm for the free-standing pellicle film of HARM-structures;
minimum transmittance is the minimum value of the transmittance measured at the wavelength of 550 nm for the free-standing pellicle film of HARM-structures, and
wherein the free-standing pellicle film of HARM-structures comprises at most 10 defects per cm2.

39. The free-standing pellicle film of claim 38, wherein the free-standing pellicle film of HARM-structures exhibits a transmittance difference value of one of at most 0.8%, or at most 0.7%, or at most 0.6%, or at most 0.5%, or at most 0.4%, or at most 0.35%, at most 0.33%, or at most 0.30%, or at most 0.25%, or at most 0.20%, or at most 0.15%, or at most 0.10%, or at most 0.05%.

40. The free-standing pellicle film of claim 38, wherein the free-standing pellicle film of HARM-structures comprises one of at most 5, or at most 3, or at most 1, or 0, defect(s) per cm2.

41. The free-standing pellicle film of claim 38, wherein the thickness of the free-standing pellicle film is one of 75-400 nm, or 76-350 nm, or 77-300 nm, or 78-250 nm, or 79-200 nm, or 80-160 nm, or 81-140 nm, or 82-120 nm, or 83-110 nm, or 84-100 nm, or 85-90 nm.

42. The free-standing pellicle film of claim 38, wherein the free-standing pellicle film is one of a pellicle film for extreme ultraviolet lithography; an extreme ultraviolet membrane; an extreme ultraviolet debris filter; or a pellicle film for an X-ray window.

43. The free-standing pellicle film of claim 38, wherein the frame comprises at least one of polymer, quartz, titanium, graphite, silicon, silicon carbide, silicon nitrate, poly-silicon, a transition metal, or an alloy of a transition metal.

44. The free-standing pellicle film of claim 38, wherein the HARM-structures comprise carbon nanostructures.

45. The use of the free-standing pellicle film of claim 38, in extreme ultraviolet lithography; as an extreme ultraviolet membrane; as an extreme ultraviolet debris filter; or as a pellicle film for an X-ray window.
